(19) United States
(12) Patent Application Publication
(10) Pub. No.: US 2025/0241184 A1
(43) Pub. Date: Jul. 24, 2025

(54) LIGHT EMITTING DISPLAY DEVICE

(71) Applicant: LG Display Co., Ltd., Seoul (KR)

(72) Inventor: Jong Ho KIM, Paju-si (KR)

(73) Assignee: LG Display Co., Ltd., Seoul (KR)

(21) Appl. No.: 19/034,342

(22) Filed: Jan. 22, 2025

(30) Foreign Application Priority Data
Jan. 23, 2024 (KR) 10-2024-0010178

(51) Int. Cl. H10K 59/80; H10D 86/40; H10D 86/60; H10K 59/121; H10K 59/122; H10K 59/126; H10K 59/60

(52) U.S. Cl. CPC H10K 59/879; H10K 59/1213; H10K 59/122; H10K 59/126; H10K 59/60; H10K 59/873; H10D 86/421; H10D 86/60

(57) ABSTRACT

A light emitting display device can include a substrate having a first area and a second area, a plurality of first light emitting units provided in the first area, a second light emitting unit and a transmission unit provided in the second area, a pixel defining film disposed to surround the plurality of first light emitting units and the second light emitting unit, and a lens layer provided in the transmission unit. The lens layer can include a first refractive index layer and a second refractive index layer located on the first refractive index layer and having a higher refractive index than the first refractive index layer. Further, the lens layer has a curved interface provided between the first refractive index layer and the second refractive index layer.

### CROSS-REFERENCE TO RELATED APPLICATIONS

This application claims priority to Korean Patent Application No. 10-2024-0010178, filed in the Republic of Korea on Jan. 23, 2024, the entire contents of which are hereby expressly incorporated by reference into the present application.

### BACKGROUND OF THE INVENTION

### Field of the Invention

The present disclosure relates to a display device, and more particularly to a light emitting display device capable of improving sensitivity of a sensor unit and improving reliability of internal elements of the light emitting display device.

### Discussion of the Related Art

Display devices for displaying images on TVs, monitors, smartphones, tablet computers, and laptop computers, etc. are used in various ways and forms.

A display device includes a plurality of pixels configured to display an image and a transistor configured to control the operation of each pixel.

Among the display devices, a light emitting display device having a light emitting element in a display panel without a separate light source for compactness of the device and clear color display is considered to have a competitive edge.

The light emitting element can include an anode and a cathode disposed opposite each other as electrodes, a light emitting layer provided between the anode and the cathode, and a common layer configured to transfer holes and electrons to the light emitting layer.

Meanwhile, in recent years, a structure including a transmission unit to increase the transmittance of the display device has been considered, and various research and development thereon has been conducted.

### SUMMARY OF THE INVENTION

Embodiments of the present disclosure provide a light emitting display device having improved sensitivity of a sensor unit of the light emitting display device.

Embodiments of the present disclosure provide a light emitting display device capable of improving reliability of a transistor of the light emitting display device.

Embodiments of the present disclosure provide a light emitting display device having a transmission unit, wherein a lens layer is provided in the transmission unit to improve light collection efficiency, thereby increasing a light detection rate of the transmission unit, and a light-shielding film is provided between the transmission unit and an area adjacent thereto to prevent deterioration of an element due to transmission of side light.

Embodiments of the present disclosure provide a light emitting display device capable of reducing or minimizing the defect rate of the display device, thereby reducing the quantity or amount of materials used in the overall manufacturing process, such as gas and etching liquid for manufacturing the display device, and thus reducing greenhouse gas generation due to the manufacturing process.

A light emitting display device according to an embodiment of the present disclosure includes a substrate having a first area and a second area, a plurality of first light emitting units provided in the first area, a second light emitting unit and a transmission unit provided in the second area, the second light emitting unit and the transmission unit being spaced apart from each other, a pixel defining film disposed so as to surround the plurality of first light emitting units and the second light emitting unit, and a lens layer provided in the transmission unit, the lens layer comprising a first refractive index layer and a second refractive index layer located on the first refractive index layer and having a higher refractive index than the first refractive index layer, the lens layer having a curved interface provided between the first refractive index layer and the second refractive index layer.

A light emitting display device according to an embodiment of the present disclosure comprise a substrate including a display area and a non-display area surrounding the display area; a plurality of subpixels emitting light provided in the display area and a transmission unit located between the subpixels; and a sensor unit disposed so as to correspond to the transmission unit, wherein a concave portion from which at least one insulating film on the substrate has been removed is provided in the transmission unit, and a lens layer is provided in the concave portion such that light incident on the substrate from above is condensed through the lens layer and collected by the sensor unit.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a schematic plan view showing a light emitting display device according to one or more embodiments of the present disclosure;

FIG. 2 is a circuit diagram showing a subpixel according to an embodiment of the present disclosure;

FIG. 3 is an enlarged view of area A of FIG. 1;

FIG. 4 is a sectional view taken along lines I-I′ and II-II′ of FIG. 3;

FIG. 5 is a sectional view showing a transmission unit of FIG. 3;

FIGS. 6A to 6E are process sectional views showing a method of manufacturing a light emitting display device according to an embodiment of the present disclosure; and

FIG. 7 is a sectional view showing a light emitting display device according to another embodiment of the present disclosure.

### DETAILED DESCRIPTION OF THE EMBODIMENTS

Hereinafter, various embodiments of the present disclosure will be described with reference to the accompanying drawings. Wherever possible, the same reference numbers will be used throughout the drawings to refer to the same or like parts, unless otherwise specified. In the following description of the present disclosure, where the detailed description of the relevant known steps, elements, functions, technologies, and configurations can unnecessarily obscure an important point of the present disclosure, a detailed description of such steps, elements, functions, technologies, and configurations can be omitted. In addition, the names of elements used in the following description are selected in consideration of clarity of description of the specification, and can differ from the names of elements of actual products.

The shapes, sizes, ratios, angles, numbers, and the like, which are illustrated in the drawings to describe various example embodiments of the present disclosure are merely given by way of example. The disclosure is not limited to the illustrations in the drawings. In the present disclosure, where terms such as “including,” “having,” “comprising,” and the like are used, one or more components can be added, unless the term, such as “only,” is used. The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “under” and “next to”, at least one intervening element can be present between the two elements, unless “immediate(ly)” or “direct(ly)” or “close(ly) is used. It will be understood that when an element or layer is referred to as being “connected to”, or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms aim to distinguish the same or similar components from one another and do not limit the components. Accordingly, throughout the specification, a “first” component can be the same as a “second” component within the technical concept of the present disclosure, unless specifically mentioned otherwise.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship. Further, the term “can” fully encompasses all the meanings and coverages of the term “may.” All the components of each light emitting display device according to all embodiments of the present disclosure are operatively coupled and configured.

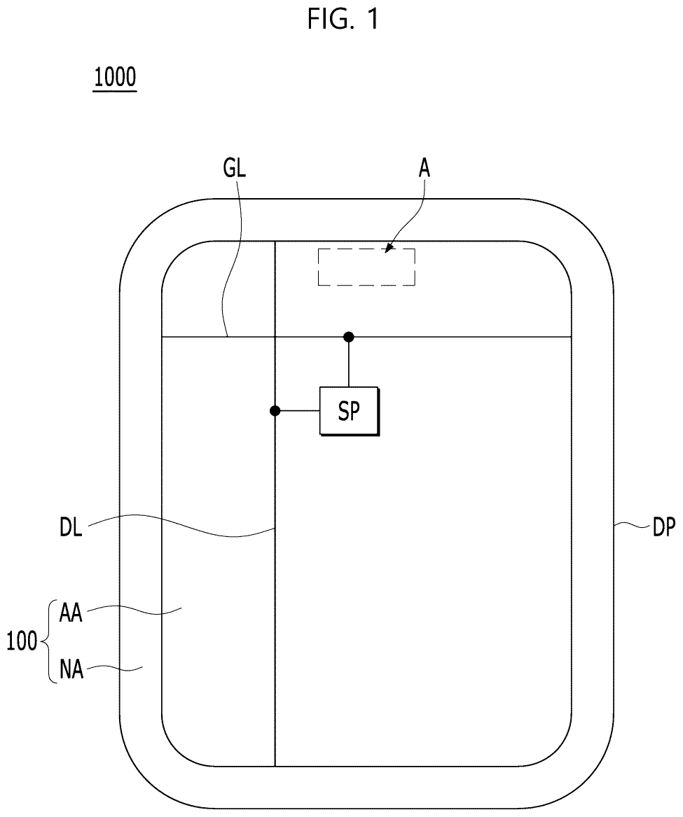

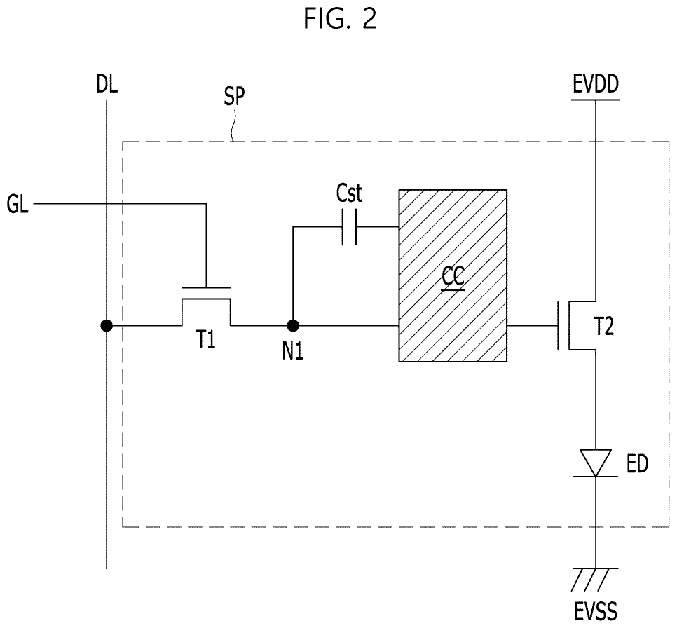

FIG. 1 is a schematic plan view showing a light emitting display device according to one or more embodiments of the present disclosure, and FIG. 2 is a circuit diagram showing a subpixel according to an embodiment of the present disclosure.

Referring to FIGS. 1 and 2, a display device 1000 according to the embodiments of the present disclosure can include a display panel DP, wherein the display panel DP can include a substrate 100 including a display area AA (or active area) and a non-display area NA (non-active area) surrounding the display area AA, and a driving unit connected to the substrate 100. The non-display area NA can surround the display area AA entirely or only in part(s). The driving unit can be integrated into the substrate 100 and formed together with an array provided in the display area AA, can be chip-on-glass (COG) connected to the substrate 100, can be chip-on-film (COF) connected to the substrate 100, or can be connected to a printed circuit board via a connector.

The display area AA is an area configured to display an image. A plurality of subpixels SP can be disposed in the display area AA of the display panel DP, and an image can be displayed using the plurality of subpixels SP.

The display device 1000 can include a display panel DP and a case configured to receive the side of the display panel DP and the bottom of the display panel DP. The non-display area NA of the display panel DP can be hidden by the case or covered by a separate printed film. A printed circuit film and/or a battery can be provided between the bottom of the display panel DP and the case.

The area where the plurality of subpixels SP is disposed can be the display area AA, and the area other than the display area AA can be the non-display area NA.

The non-display area NA can an edge area surrounding the display area AA that displays the image. At least one driving unit configured to drive the plurality of subpixels SP can be disposed in the non-display area NA. The driving unit can include a gate-in-panel (GIP). The gate-in-panel (GIP) can be connected to a plurality of gate lines GL in the display area AA, and can sequentially supply a gate voltage signal to the plurality of gate lines GL.

Various additional elements configured to drive the subpixels SP in the display area AA can be further disposed in the non-display area NA.

At least one of the plurality of subpixels SP can include a first transistor T1, a second transistor T2, a storage capacitor Cst, a compensation circuit CC, and a light emitting element ED, as shown in FIG. 2.

In one example, the first transistor T1 can be a switching transistor and the second transistor T2 can be a driving transistor.

A first electrode (e.g., a drain electrode) of the first transistor T1 is electrically connected to a data line DL, and a second electrode (e.g., a source electrode) of the first transistor T1 is electrically connected to a first node N1. A gate electrode of the first transistor T1 is electrically connected to a gate line GL. The first transistor T1 transmits a data signal supplied via the data line DL to the first node N1 in response to a scan signal supplied via the gate line GL.

The storage capacitor Cst is electrically connected to the first node N1 to charge voltage applied to the first node N1.

A first electrode (e.g., a drain electrode) of the second transistor T2 receives a high potential drive voltage (EVDD), and a second electrode (e.g., a source electrode) of the second transistor T2 is electrically connected to a first electrode (e.g., an anode) of the light emitting element ED. The second transistor T2 can control the amount of driving current flowing to the light emitting element ED in response to voltage applied to the gate electrode.

A semiconductor layer of the first transistor T1 and/or the second transistor T2 can include, without being limited to, silicon such as amorphous silicon (a-Si), polycrystalline silicon (poly-Si), or low-temperature polycrystalline silicon (poly-Si), or an oxide, such as indium-gallium-zinc-oxide (IGZO). At least one of the first and second transistors T1 and T2 can include an oxide semiconductor layer, which can be formed at a lower temperature than other materials, can maintain amorphous properties, and can have high mobility.

The light emitting element ED outputs light corresponding to the driving current. The light emitting element ED can output light corresponding to any one of red, green, blue, and white.

The light emitting element ED can include an anode, a light emitting layer disposed on the anode, and a cathode to which a common voltage is supplied. The light emitting layer can be configured to emit the same color of light on a pixel-by-pixel basis, such as white light, or can be configured to emit different colors on a subpixel-by-subpixel basis, such as red, green, or blue light.

The light emitting element ED can be a front-emitting diode or a back-emitting diode.

The compensation circuit CC can be provided in the subpixel SP to compensate for a threshold voltage of the second transistor T2. The compensation circuit CC can include one or more transistors. The compensation circuit CC can include one or more transistors and capacitors, and can be variously configured depending on a compensation method. The subpixel including the compensation circuit CC can include various circuits with different numbers of transistors and/or capacitors, such as 3T1C, 4T2C, 5T2C, 6T1C, 6T2C, 7T1C, and 7T2C.

Meanwhile, the display panel DP can have a camera or a sensor provided in a part (area A) of the display area AA, as shown in FIG. 1. The camera or the sensor can be provided on the bottom side of the substrate 100, or a hole can be provided in the substrate 100 such that a part of the camera or the sensor can be inserted into the hole in the substrate 100 from the bottom side of the substrate 100.

The sensor detects light, and can be, for example, an infrared sensor or an ultraviolet sensor depending on the wavelength of light collected.

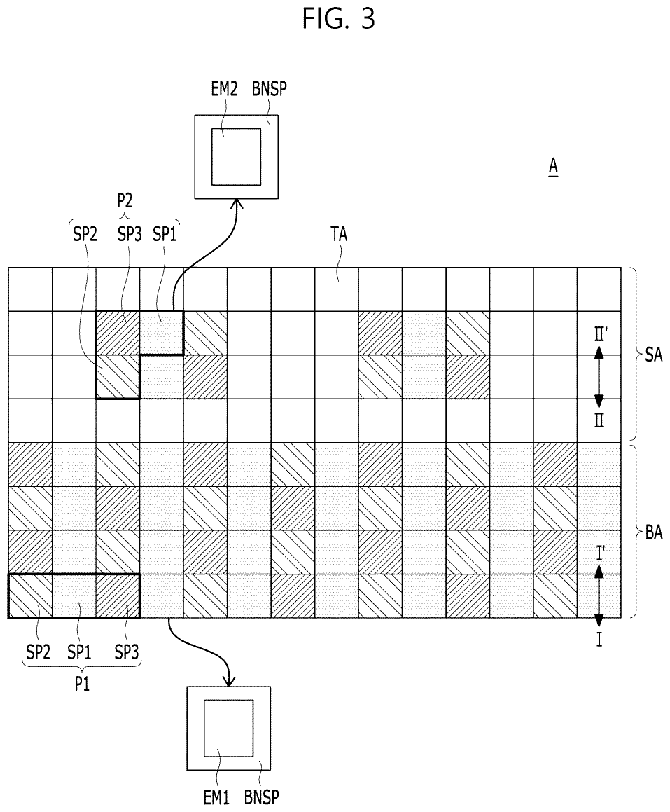

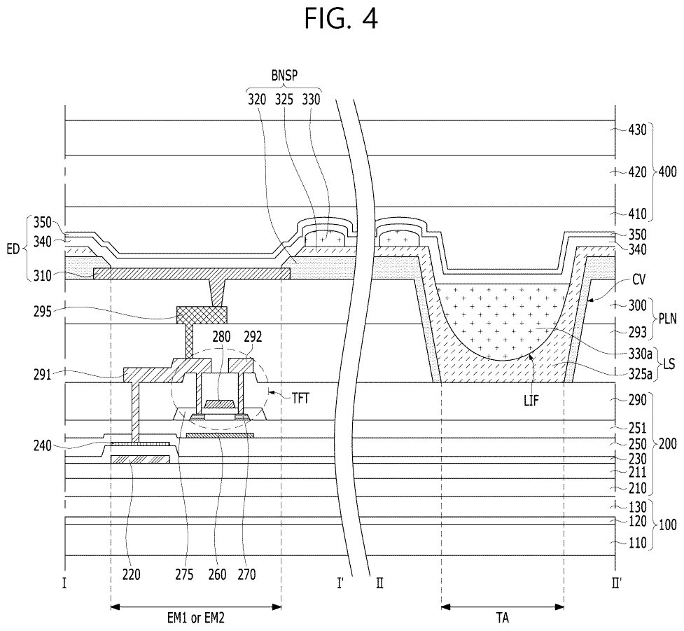

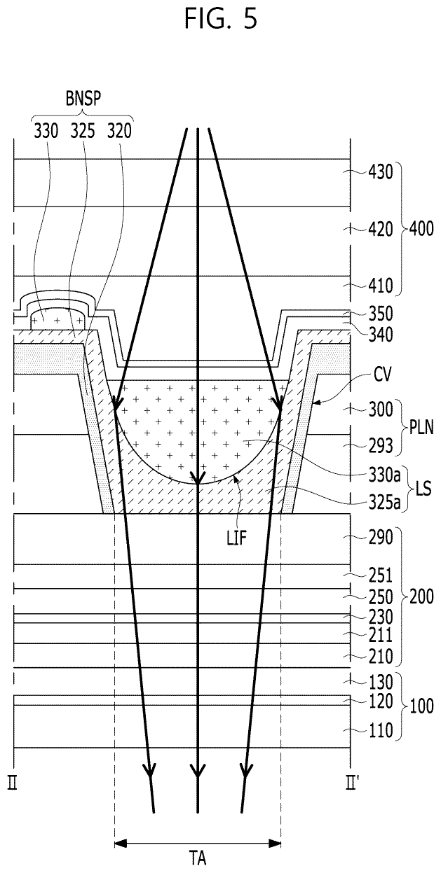

FIG. 3 is an enlarged view of area A of FIG. 1, and FIG. 4 is a sectional view taken along lines I-I′ and II-II′ of FIG. 3. FIG. 5 is a sectional view showing a transmission unit of FIG. 3.

As shown in FIG. 3, the area in which the camera or the sensor is located can include a transmission unit TA to sense an image or light from the top side of the substrate 100.

In the following description, the area where the camera or the sensor is not located and normal subpixels SP1, SP2, and SP3 are provided is referred to as a first area BA, and the area where the camera or the sensor is located is referred to as a second area SA.

In the light emitting display device according to the embodiments of the present disclosure, the camera or the sensor is provided in the second area SA, which is a part of the display area AA, in which the subpixels SP1, SP2, and SP3 are included. However, the second area SA is further provided with a transmission unit TA for light sensing by the camera or the sensor, whereby the second area SA can have lower resolution due to lower arrangement density of the subpixels SP1, SP2, and SP3 than in the first area BA.

The adjacent subpixels SP1, SP2, and SP3 of the first area BA and the second area SA include light emitting elements ED configured to emit different light emitting colors, and each light emitting element ED has a light emitting unit EM1 or EM2 surrounded by a pixel defining film BNSP, as shown in FIG. 4. In each of the subpixels SP1, SP2, and SP3, the light emitting element ED is connected to a transistor TFT.

The first area BA includes subpixels SP1, SP2, and SP3 configured to emit different colors as one first pixel P1, and the first pixel P1 is provided in the first area BA with first resolution. The second area SA includes subpixels SP1, SP2, and SP3 configured to emit different colors as one second pixel P2, and the second pixel P2 is provided in the second area SA together with the transmission unit TA while having a second resolution lower than the first resolution.

Since the second pixel P2 is provided in the second area SA while having lower resolution than the first pixel P1 in the first area BA and no transistors are provided in the area occupied by the transmission unit TA in the second area SA, the density of disposition of the transistors relative to the area is lower than in the first area BA. In order to have the same light emitting characteristics as the first area BA, therefore, the transistors TFT in the second area SA can have higher sensitivity than the transistors TFTs in the first area BA. In this case, the mobility of the transistors TFT in the second area SA can be higher than the mobility of the transistors TFT in the first area BA. In one example, the materials of the semiconductor layers of the transistors in the first area BA and the second area SA can be different from each other in order to have a difference in mobility.

Meanwhile, different mobility characteristics can also be required among the plurality of transistors provided in each subpixel of the first and second areas BA and SA. For example, the switching transistors can have higher mobility than the driving transistors for gradation expression since high speed response is required.

The transistor can be provided in the driving unit of the non-display area NA as well as the subpixel SP, wherein the transistor provided in the non-display area NA can require higher mobility than the driving transistor in the display area AA.

As shown in FIGS. 3 and 4, the light emitting display device according to the embodiments of the present disclosure includes a substrate 100 having a first area BA and a second area SA, a plurality of first light emitting units EM1 provided in the first area BA, a second light emitting unit EM2 and a transmission unit TA provided in the second area SA so as to be spaced apart from each other, and a pixel defining film BNSP surrounding the plurality of first light emitting units EM1 and the second light emitting unit EM2.

The transmission unit TA of the second area SA can include a lens layer LS including a first refractive index layer 325a and a second refractive index layer 330a located on the first refractive index layer 325a and having a higher refractive index than the first refractive index layer 325a.

As shown in FIGS. 4 and 5, the lens layer LS can have a curved interface LIF between the first refractive index layer 325a and the second refractive index layer 330a, and can increase light collection efficiency of light incident on the substrate 100 from above. The curved interface LIF is located in a concave portion CV from which at least a planarization film PLN configured to protect the transistor TFT has been removed, and, in one example, the curved interface LIF can be in the shape of a concave lens recessed so as to face a lower surface of the concave portion CV. Light incident on the substrate 100 from above can be condensed at the curved interface LIF and collected by the camera or the sensor at the bottom side of the substrate 100 with improved light collection efficiency.

The curved interface LIF of the lens layer LS has a surface area greater than the surface area of the lower surface of the concave portion, and can increase the light collection efficiency of the camera or the sensor disposed at the bottom side of the substrate 100.

The pixel defining film BNSP can include a light-shielding pixel defining film 320 and a light-transmissive pixel defining film 325. The pixel defining film BNSP can further include a spacer 330 provided on a part of the light-transmissive pixel defining film 325 to prevent a deposition mask from coming into contact with the light-shielding pixel defining film 320 and/or the light-transmissive pixel defining film 325 during deposition, thereby preventing dent defects, etc.

The light-shielding pixel defining film 320 can include a black material, such as black pigment or light-shielding particles, to prevent incidence of light on the peripheral area of the light emitting unit from above.

The first refractive index layer 325a can be made of the same material as the light-transmissive pixel defining film 325 surrounding the light emitting units EM1 and EM2 of each subpixel in the first and second areas BA and SA. In the second area SA, the first refractive index layer 325a can extend from the transmission unit TA to the light-transmissive pixel defining film 325 of the pixel defining film BNSP of the subpixels SP1, SP2, and SP3 in the second pixel P2 adjacent thereto. In this case, the first refractive index layer 325a can be integrated with the light-transmissive pixel defining film 325.

The second refractive index layer 330a can be made of the same material as the spacer 330 in the same process. The second refractive index layer 330a can have a refractive index higher than the refractive index of the first refractive index layer 325a, whereby refraction can occur at the curved interface LIF where the first and second refractive index layers 325a and 330a are joined to each other, and light can be collected to the bottom side of the substrate 100 by the curved shape of the curved interface LIF and can be emitted therefrom.

The light emitting element ED provided in each of the subpixels SP1, SP2, and SP3 of the first area BA and the second area SA includes an anode 310, an intermediate layer 340, and a cathode 350.

The light emitting element ED is coupled to at least one transistor TFT.

In one example, the transistor TFT can include a semiconductor layer 270, a gate electrode 280, a first source-drain electrode 291, and a second source-drain electrode 292.

When the semiconductor layer 270 is made of, for example, an oxide semiconductor, a light-shielding pattern 260 can be further provided thereunder to prevent influence by bottom light.

In addition to the transistor TFT, each subpixel can include a storage capacitor including a first storage electrode 220 and a second storage electrode 240 overlapping each other. At least one insulating film 230 can be provided between the first storage electrode 220 and the second storage electrode 240. Any one of the first storage electrode 220 and the second storage electrode 240 can be connected to any one of the first source-drain electrode 291 and the second source-drain electrode 292 of the transistor TFT.

Any one of the first source-drain electrode 291 and the second source-drain electrode 292 of the transistor TFT can be connected to the anode 310 of the light emitting element ED via a connection electrode 295.

The light emitting display device according to the embodiments of the present disclosure includes one or more planarization films PLN (293 and 300) provided between the light emitting element ED and the transistor TFT, and the transmission unit TA of the second area SA can include a concave portion CV from which one or more insulating films including the planarization film PLN have been removed.

A pixel defining film BNSP is provided between the transmission units TA, between the transmission unit TA and the light emitting unit EM2, and between the neighboring light emitting units EM1 and EM2. Particularly, the light-shielding pixel defining film 320 can prevent incidence of light on various transistors TFT provided in the display area AA or the non-display area NA of the substrate 100 from above, thereby preventing the transistors from being affected by external light. The light-shielding pixel defining film 320 can block light from above and prevent change of characteristics of the transistors TFT caused from incidence of light.

Also, in the light emitting display device according to the embodiments of the present disclosure, the light-shielding pixel defining film 320 is provided on the side of the concave portion CV from which the planarization film PLN has been removed in the area where the transmission unit TA is located, thereby preventing a thin-film transistor constituted by an oxide semiconductor layer and having high mobility, among various transistors provided in the display area AA or the non-display area NA of the substrate 100, from being affected by side scattered light.

In the light emitting display device according to the embodiments of the present disclosure, the concave portion CV is provided in the transmission unit TA, and the lens layer LS in which the curved interface LIF is defined is provided in the concave portion, whereby the light collection efficiency of the camera or the sensor at the bottom side of the substrate 100 is increased. In addition, the light-shielding pixel defining film 320 is provided along the side surrounding the concave portion CV, transmission of side scattered light around the transmission unit TA is prevented by the light-shielding pixel defining film 320, and the influence of external light on the transistor TFT in the light emitting display device can be prevented. As a result, the operation of the transistor can be stabilized and deterioration can be prevented.

The light-shielding pixel defining film 320 can effectively prevent the transmission of light to the side, even though the thickness of the light-shielding pixel defining film 320 is small on the side of the concave portion CV, thereby maintaining the light collection efficiency of the lens layer LS in the transmission unit TA to improve the sensing sensitivity of the camera or the sensor while preventing light loss at the transmission unit.

Each of the first refractive index layer 325a and the light-transmissive pixel defining film 325 can have a refractive index of, for example, 1.4 to 1.6. In one example, each of the first refractive index layer 325a and the light-transmissive pixel defining film 325 can be made of a material such as a polyacrylic resin.

Each of the second refractive index layer 330a and the spacer 330 can have a refractive index of, for example, 1.8 to 2.2. In one example, each of the second refractive index layer 330a and the spacer 330 can be made of a material such as a polyimide resin.

In addition to the above examples, the materials of the first and second refractive index layers 325a and 330a can be changed to other materials as long as the refractive index difference between the first and second refractive index layers 325a and 330a is 0.2 or more and the curved interface therebetween increases the light collection efficiency of the camera or the sensor at the bottom side of the substrate 100.

Hereinafter, the configuration of the light emitting display device according to one or more embodiments of the present disclosure will be described in detail with reference to FIGS. 4 and 5.

Referring to FIGS. 4 and 5, the substrate 100 can be made of a plastic material so as to be flexible. In one example, the substrate 100 can include first and second organic films 110 and 130 overlapping each other with an inorganic interlayer insulating film 120 therebetween. Each of the first and second organic films 110 and 130 can include, for example, polyimide. In addition to polyimide, the first and second organic films 110 and 130 can include different organic films. In another example, the substrate 100 can include a flexible, thin glass material.

One of the first and second organic films 110 and 130 of the substrate 100 can be made of polyethylene terephthalate (PET), and the other can be made of polyimide. When the first and second organic films 110 and 130 are made of different organic materials, the substrate 100 can include an adhesive film, such as a pressure sensitive adhesive (PSA), provided therebetween.

The substrate 100 serves to support and protect the components of the display device 1000 disposed thereon.

A plurality of stacked insulating films 210, 211, 230, 250, 251, and 290 is disposed in the display area AA and the non-display area NA of the substrate 100 such that the electrodes 280, 291, and 292 constituting the transistor TFT can be insulated from each other. The insulating films can include a first insulating film 210, a second insulating film 211, a third insulating film 230, a fourth insulating film 250, a fifth insulating film 251, and a sixth insulating film 290.

The first insulating film 210 is disposed in the display area AA and the non-display area NA of the substrate 100. The first insulating film 210 can be referred to as a buffer film and can perform the same function as a buffer film known in the art. The first insulating film 210 can be disposed on the substrate 100 to protect structures located on the substrate 100 from moisture permeating through the substrate 100 and to planarize the surface of the substrate 100.

The first insulating film 210 can extend to an edge of the substrate 100 to prevent permeation of moisture from the edge of the substrate 100. The first insulating film 210 can be constituted by a single inorganic film or a plurality of alternately stacked inorganic films.

For example, the first insulating film 210 can include at least one of a silicon oxide film (SiOx), a silicon nitride film (SiNx), and a silicon oxynitride film (SiOxNy), or a multilayer film formed by stacking the inorganic films.

The second insulating film 211 can be disposed on the first insulating film 210. The second insulating film 211 can function, for example, as a second buffer layer. In this case, a part of the transistor TFT can include a polysilicon semiconductor layer, and the second insulating film 211 can be located under the polysilicon semiconductor layer. The second insulating film 211 can include an inorganic film, such as a silicon oxide film (SiOx), a silicon nitride film (SiNx), or a silicon oxynitride film (SiOxNy), or a multilayer film thereof. In some cases, the second insulating film 211 can be used as a gate insulating film of a transistor including a polysilicon semiconductor layer.

The first storage electrode 220 can be provided on the second insulating film 211. The first storage electrode 220 can be made of, for example, a conductive metal material, and specifically, the conductive metal material can include at least one of an aluminum-based metal, such as aluminum (Al) or an aluminum alloy, a silver-based metal, such as silver (Ag) or a silver alloy, a copper-based metal, such as copper (Cu) or a copper alloy, a molybdenum-based metal, such as molybdenum (Mo) or a molybdenum alloy, chromium (Cr), tantalum (Ta), neodymium (Nd), and titanium (Ti). In some cases, the first storage electrode 220 can include a doped polysilicon semiconductor layer when the driving unit or the switching transistor includes a polysilicon semiconductor layer.

The third insulating film 230 can be disposed on the second insulating film 211. The third insulating film 230 functions as an insulator between the first and second storage electrodes 220 and 240, and can also function as an interlayer insulating film of a transistor including a polysilicon semiconductor layer.

The third insulating film 230 can include an inorganic material. The inorganic material can include, for example, a silicon nitride film (SiNx).

The second storage electrode 240, which is made of a conductive metal material, can be formed on the third insulating film 230. Specifically, the conductive metal material can include at least one of an aluminum-based metal, such as aluminum (Al) or an aluminum alloy, a silver-based metal, such as silver (Ag) or a silver alloy, a copper-based metal, such as copper (Cu) or a copper alloy, a molybdenum-based metal, such as molybdenum (Mo) or a molybdenum alloy, chromium (Cr), tantalum (Ta), neodymium (Nd), and titanium (Ti).

Each of the first storage electrode 220 and the second storage electrode 240 can be a single layer, or can have a structure in which a plurality of different metal materials is stacked.

The fourth insulating film 250 can be disposed on the third insulating film 230. The fourth insulating film 250 can be located under the oxide semiconductor layer 270 and the light-shielding pattern 260 and can function as a buffer layer. The fourth insulating film 250 can serve to planarize the surface of the area where the transistor TFT is formed, including the oxide semiconductor layer 270 disposed thereon.

The fourth insulating film 250 can include an inorganic material. The inorganic material can include, for example, a silicon oxide film (SiOx) or a multilayer film formed by stacking inorganic films.

The light-shielding pattern 260 configured to prevent light from being incident on the oxide semiconductor layer 270 located thereon from below can be provided on the fourth insulating film 250.

The light-shielding pattern 260 can be made of a conductive material, such as a metal. The light-shielding pattern 260 can be made of a single metal, and can also be made of two or more metals or two or more metal alloys. In addition, the light-shielding pattern 260 can have a single layer structure or a multilayer structure.

The fifth insulating film 251 can be disposed on the fourth insulating film 250.

The fifth insulating film 251 can include an inorganic material. The inorganic material can include, for example, a silicon oxide film (SiOx) or a multilayer film formed by stacking inorganic films.

When each of the fourth and fifth insulating films 250 and 251 is constituted by a silicon oxide film, no hydrogen particles are discharged during heat treatment, thereby preventing a decrease in reliability of the oxide semiconductor layer 270 disposed adjacent to the fourth and fifth insulating films 250 and 251 due to hydrogen particles.

The oxide semiconductor layer 270 formed on the fifth insulating film 251 includes an oxide semiconductor material. The oxide semiconductor material can include a combination of at least one of zinc (Zn), indium (In), gallium (Ga), tin (Sn), and titanium (Ti) and an oxide. In some cases, a highly conductive metal, such as iron (Fe), can be further included in the oxide semiconductor material to increase mobility.

More specifically, the oxide semiconductor material constituting the oxide semiconductor layer 270 can be, for example, zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), or iron-indium-zinc oxide (FIZO).

A gate insulating film 275 can be disposed between the oxide semiconductor layer 270 and the gate electrode 280. The gate insulating film 275 can be formed so as to cover the top and the side of the oxide semiconductor layer 270, as shown, or can extend to the side so as to be formed in the entirety of the display area AA and the non-display area NA. In some cases, the gate insulating film 275 can be provided only between a channel area of the oxide semiconductor layer 270 and the gate electrode 280.

The gate insulating film 275 is made of an inorganic insulating material and can include, for example, a silicon oxide film (SiOx), a silicon nitride film (SiNx), or a multilayer film formed by stacking inorganic films.

The undoped part of the oxide semiconductor layer 270 overlapping the gate electrode 280 can function as the channel of the oxide semiconductor layer 270. The doped area of the oxide semiconductor layer 270 is formed using the gate electrode 280 as a mask. The doped area of the oxide semiconductor layer 270 corresponds to an area located on each side of the gate electrode 280, and the doped area of the oxide semiconductor layer 270 is connected to the first and second source-drain electrodes 291 and 292 spaced apart from each other and can function as a conductive source-drain area.

The gate electrode 280 can be made of a conductive metal material. Specifically, the conductive metal material can include at least one of an aluminum-based metal, such as aluminum (Al) or an aluminum alloy, a silver-based metal, such as silver (Ag) or a silver alloy, a copper-based metal, such as copper (Cu) or a copper alloy, a molybdenum-based metal, such as molybdenum (Mo) or a molybdenum alloy, chromium (Cr), tantalum (Ta), neodymium (Nd), and titanium (Ti). The gate electrode 280 can have a multilayer film structure including at least two conductive metal materials.

The sixth insulating film 290 can be disposed on the gate electrode 280. The sixth insulating film 290 covers the top and the side of the gate electrode 280 such that the first source-drain electrode 291 and the second source-drain electrode 292 are insulated from the gate electrode 280.

The sixth insulating film 290 can be constituted by a single inorganic film or a plurality of stacked inorganic films. At least one of a silicon oxide film (SiOx), a silicon nitride film (SiNx), and a silicon oxynitride film (SiOxNy) can be selected as the inorganic film.

The first source-drain electrode 291 and the second source-drain electrode 292 can be disposed on the sixth insulating film 126. The first source-drain electrode 291 and the second source-drain electrode 292 can be disposed spaced apart from each other with the gate electrode 280 therebetween. In this case, the first source-drain electrode 291 and the second source-drain electrode 292 and the gate electrode 280 can be disposed on different layers.

Each of the first source-drain electrode 291 and the second source-drain electrode 292 can be made of a conductive metal material. Specifically, the conductive metal material can include at least one of an aluminum-based metal, such as aluminum (Al) or an aluminum alloy, a silver-based metal, such as silver (Ag) or a silver alloy, a copper-based metal, such as copper (Cu) or a copper alloy, a molybdenum-based metal, such as molybdenum (Mo) or a molybdenum alloy, chromium (Cr), tantalum (Ta), neodymium (Nd), and titanium (Ti). Each of the first source-drain electrode 291 and the second source-drain electrode 292 can have a multilayer film structure including at least two conductive metal materials.

The first source-drain electrode 291 and the second source-drain electrode 292 are connected to both sides of the channel area of the oxide semiconductor layer 270. The channel area of the oxide semiconductor layer 270 can be an undoped intrinsic area, which can be the area where carriers move when voltage is applied to the transistor TFT.

Each of the first source-drain electrode 291 and the second source-drain electrode 292 can be directly connected to the oxide semiconductor layer 270 via a contact hole of the sixth insulating film 290.

The first source-drain electrode 291 can extend so as to overlap the second storage electrode 240 and can be connected to the second storage electrode 240 through contact holes provided in the sixth insulating film 290, the fifth insulating film 251, and the fourth insulating film 250.

A first planarization film 293 configured to protect the transistor TFT and the storage capacitor can be provided on the first and second source-drain electrodes 291 and 292.

A connection electrode 295 can be further provided on the first planarization film 293, and can be connected to the first source-drain electrode 291 via a contact hole in the first planarization film 293. The connection electrode 295 can be made of, for example, a conductive metal material. Specifically, the conductive metal material can include at least one of an aluminum-based metal, such as aluminum (Al) or an aluminum alloy, a silver-based metal, such as silver (Ag) or a silver alloy, a copper-based metal, such as copper (Cu) or a copper alloy, a molybdenum-based metal, such as molybdenum (Mo) or a molybdenum alloy, chromium (Cr), tantalum (Ta), neodymium (Nd), and titanium (Ti).

A second planarization film 300 can be further disposed on the connection electrode 295. An anode 310 can be further provided on the second planarization film 300, and can be connected to the connection electrode 295 via a contact hole in the second planarization film 300.

The anode 310 can include, for example, a reflective electrode and can function to prevent incidence of light on the transistor TFT under the light emitting units EM1 and EM2. The anode 310 can include, for example, a structure in which a first transparent electrode, a reflective electrode, and a second transparent electrode are stacked. The second transparent electrode, which is the uppermost electrode of the anode 310, can be a dielectric, which can lower the barrier to hole injection at the interface with the intermediate layer 340. Here, each of the first and second transparent electrodes can be a transparent oxide electrode such as ITO or IZO. The reflective electrode can include silver, a silver alloy such as APC (Ag—Pd—Cu), aluminum, or an aluminum alloy.

The first planarization film 293 and the second planarization film 300 are made of organic materials and can be functionally referred to as planarization films PLN.

In some cases, the connection electrode 295 can be omitted and the planarization film PLN can be formed in a single layer. In this case, the first source-drain electrode 291 can be directly connected to the anode 310.

The concave portion CV provided in the planarization film PLN can be formed through a removal process of the planarization film PLN during formation of the contact hole in the second planarization film 300 for connection between the anode and the connection electrode.

The pixel defining film BNSP can be formed by sequentially stacking the light-shielding pixel defining film 320 and the light-transmissive pixel defining film 325 around the light emitting units EM1 and EM2 of the anode 310. A part of the pixel defining film BNSP can further include a spacer 330.

In forming the light-shielding pixel defining film 320, the light-shielding pixel defining film 320 can be formed along the side of the concave portion CV from which the planarization film PLN has been removed so as to correspond to the transmission unit TA to shield light directed to the side between the concave portion CV and the periphery thereof. In order to increase the transmittance of the transmission unit TA, the light-shielding pixel defining film 320 is removed such that no light-shielding pixel defining film 320 corresponds to the transmission unit TA.

The first refractive index layer 325a, which is formed together with the light-transmissive pixel defining film 325, is made of a material such as a liquid polyacrylic resin and remains along the side wall of the concave portion CV and the lower part of the concave portion CV, the surface of the first refractive index layer is concave due to the surface tension of the liquid material, and the first refractive index layer is provided in the concave portion CV and the periphery thereof.

The spacer 330 is provided in a part of the pixel defining film BNSP, and is formed by liquefying an organic material having a higher refractive index than the first refractive index layer 325a. Upon formation of the spacer 330 on the light-transmissive pixel defining film 325, the material of the spacer 330 fills the concave surface of the first refractive index layer 325a in the concave portion CV and can be defined as the second refractive index layer 330a.

The first and second refractive index layers 325a and 330a together constitute the lens layer LS.

The light emitting element ED includes an anode 310, an intermediate layer 340, and a cathode 350. After forming the anode 310, the pixel defining film BNSP and the lens layer LS can be formed, and the intermediate layer 340 and the cathode 350 can be sequentially disposed on the light emitting units EM1 and EM2 of the anode 310, the pixel defining film BNSP, and the transmission unit TA.

The intermediate layer 340 can include a hole injection layer, a hole transport layer, a light emitting layer, an electron transport layer, and an electron injection layer. The intermediate layer 340 can be formed in a tandem structure including a plurality of stacks, each including a hole transport layer, a light emitting layer, and an electron transport layer, and a charge generating layer provided between the stacks. The charge generating layer can include, for example, an n-type charge generating layer and a p-type charge generating layer.

The cathode 350 can be formed by thinning a transmissive electrode, such as ITO or IZO, or a reflective-transmissive electrode, such as silver, a silver alloy, magnesium, a magnesium alloy, ytterbium (Yb), or ytterbium alloy. In another embodiment, the cathode 350 can be partially removed from the transmission unit TA or formed with a small thickness in order to increase transmittance in the transmission unit TA.

A capping layer can be further formed on the cathode 350 to protect the cathode 350 of the light emitting element ED and to increase light emission efficiency in an upward direction.

An encapsulation layer structure 400 is provided on the cathode 350 to prevent permeation of moisture into internal components and to protect the internal components from external air.

In one example, the encapsulation layer structure 400 can include a structure in which inorganic films 410 and 430 and an organic film 420 are stacked. However, the present disclosure is not limited thereto, and the encapsulation layer structure 400 can include an encapsulation substrate, such as glass. An adhesive layer can be further provided between the encapsulating substrate and the light emitting element ED facing each other.

The concave portion CV is not limited to being provided only in the planarization film PLN, unlike the example shown. For example, not only the planarization film PLN corresponding to the transmission unit TA but also the sixth insulating film 290 thereunder can be further removed to form the concave portion CV. In this case, the light-shielding pixel defining film 320 is disposed along the side of the concave portion CV, whereby the light-shielding pixel defining film 320 can be disposed on the same layer as the oxide semiconductor layer 270 to more effectively prevent a side light scattering phenomenon from the transmission unit TA to the area adjacent thereto.

Hereinafter, a method of forming the lens layer in the concave portion according to aspects of the present disclosure will be described with reference to process sectional views.

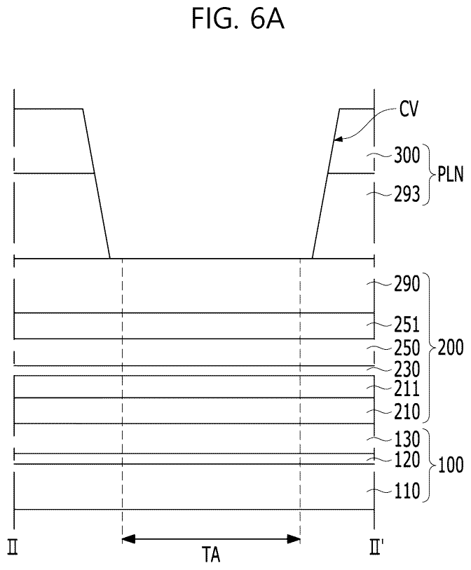

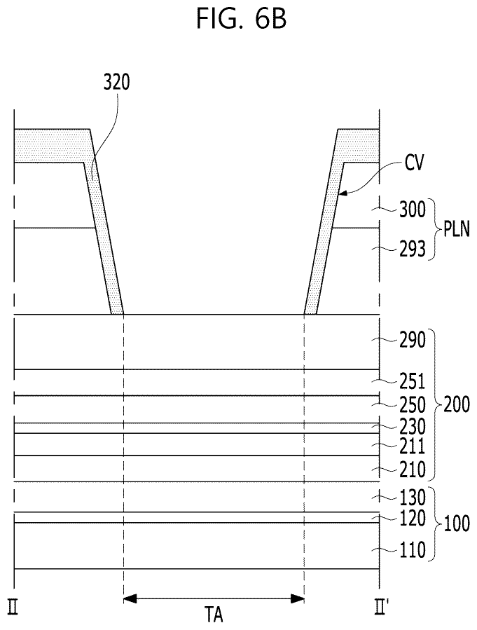

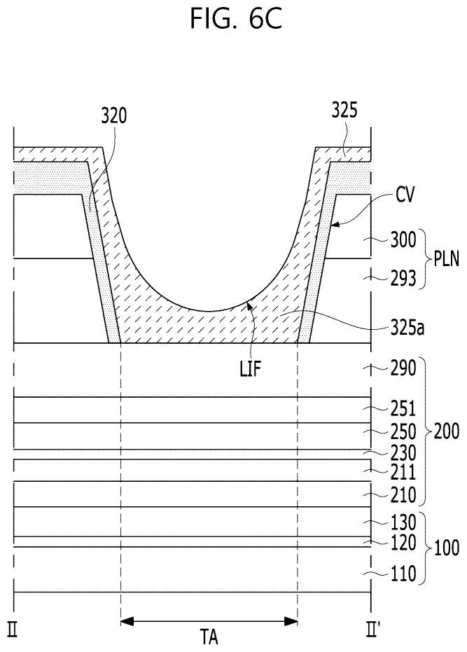

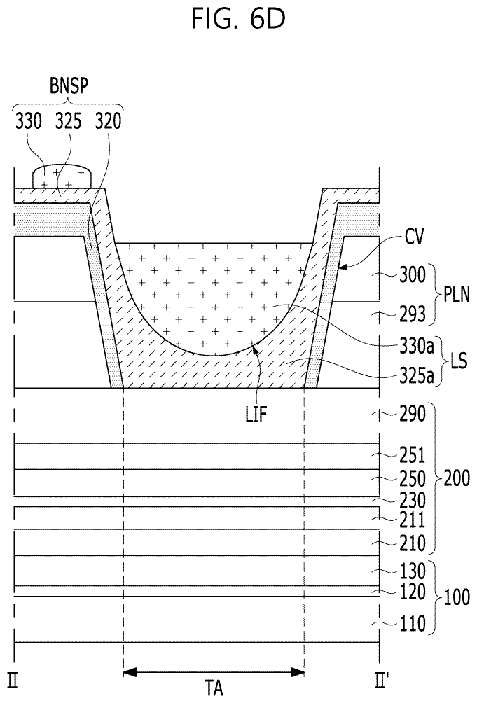

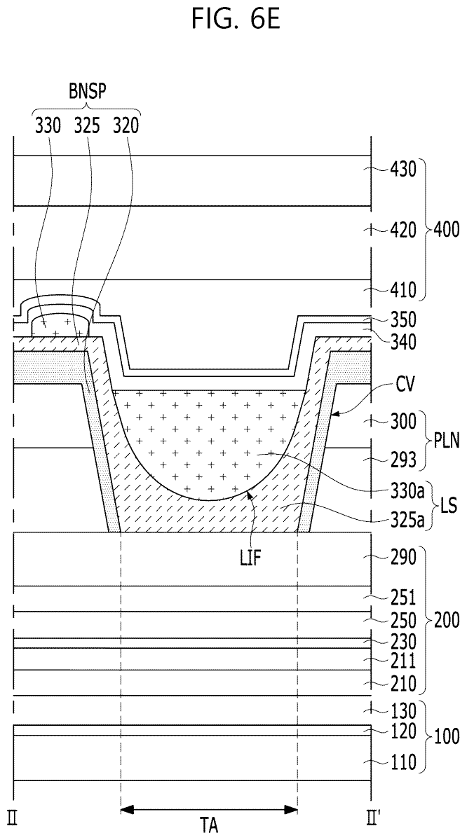

Particularly, FIGS. 6A to 6E are process sectional views showing a method of manufacturing a light emitting display device according to one or more embodiments of the present disclosure.

As shown in FIG. 6A, a first planarization film material and a second planarization film material are sequentially formed on an insulating film 200, and the second planarization film material and the first planarization film material in the area corresponding to a transmission unit TA are removed to form first and second planarization films 293 and 300 having a concave portion CV. The stacked first and second planarization films 293 and 300 having the concave portion CV are referred to herein as planarization films PLN.

Here, the concave portion CV is in the shape of a hole. The concave portion CV is formed slightly wider than the transmission unit TA in consideration of the space in which a light-shielding pixel defining film that is formed on the side of the concave portion CV with a small thickness remains. The concave portion CV can be formed in the same process as formation of a contact hole in the second planarization film 300 in a first area BA and a second area SA.

After formation of the concave portion CV, an anode 310 of each of subpixels SP1, SP2, and SP3 of the first and second areas BA and SA is formed.

Subsequently, as shown in FIG. 6B, a light-shielding pixel defining film material is coated, and a light-shielding pixel defining film 320 is formed in the remaining area after removing the light-shielding pixel defining film material from light emitting units EM1 and EM2 of each of the subpixels SP1, SP2, and SP3 and the transmission unit TA. Here, the light-shielding pixel defining film 320 can be provided so as to correspond to the side of the concave portion CV located in the transmission unit TA to prevent light proceeding to the transmission unit TA from being transmitted to the side of the concave portion.

After formation of the light-shielding pixel defining film 320, a firing process can be performed to volatilize a liquid component in the light-shielding pixel defining film, thereby fixing the shape thereof.

Subsequently, as shown in FIG. 6C, a light-transmissive pixel defining film material, which is a low refractive index material, is coated in a liquid state. Here, the coating thickness of the light-transmissive pixel defining film material is less than the depth of the concave portion CV, wherein the liquid material is left as a small thickness by the surface tension of the side and the bottom of the concave portion CV, and can have a concave surface recessed into the concave portion CV. The light-transmissive pixel defining film material can be removed from the light emitting units EM1 and EM2 to form a light-transmissive pixel defining film 325 surrounding the light emitting units EM1 and EM2 and a first refractive index layer 325a that is left with a small thickness at the side and the bottom of the concave portion CV of the transmission unit TA. A curved surface of the first refractive index layer 325a can be realized by a surface adhesion difference of a sixth insulating film 290 exposed on the side of the concave portion CV where the light-shielding pixel defining film 320 is formed and the bottom of the concave portion CV where the light-shielding pixel defining film 320 is not formed.

The first refractive index layer 325a can be extended to overlap the light-shielding pixel defining film 320.

In some cases, the first refractive index layer 325a can be patterned to have a curved surface by varying the thickness of a photosensitive film configured to pattern the shape. For example, in the area corresponding to the concave portion CV of the transmission unit TA, the photosensitive film is left such that the photosensitive film gradually becomes thicker from the center of the bottom of the concave portion CV to the side thereof, the amount of light exposure is changed by the difference in the thickness of the photosensitive film, and the first refractive index layer 325a can be left such that the thickness of the first refractive index layer 325a gradually increases from the center of the bottom of the concave portion CV to the side thereof in proportion to the difference in the thickness of the photosensitive film.

After formation of the light-transmissive pixel defining film 325 and the first refractive index layer 325a, a liquid component, such as a solvent, in the light-transmissive pixel defining film material can be removed through a firing process to fix the shape thereof.

Subsequently, as shown in FIG. 6D, a spacer material, which is a high refractive index material, is coated in a liquid state to form a spacer 330 on a part of the light-transmissive pixel defining film 325. The spacer material can be left in the concave area of the concave portion CV such that a second refractive index layer 330a is formed in a part of the concave portion CV.

After formation, the spacer 330 and the second refractive index layer 330a can be subjected to a firing process to volatilize the liquid component contained in the material and fix the shape thereof.

The light-shielding pixel defining film 320, the light-transmissive pixel defining film 325, and the spacer 330 can be collectively referred to as a pixel defining film BNSP. In the pixel defining film BNSP, a lens layer LS provided in the concave portion CV of the transmission unit TA can be an integrated lens layer.

As shown in FIG. 6E, an intermediate layer 340 and a cathode 350 are formed on a surface including the pixel defining film BNSP and the lens layer LS.

The anode 310, the intermediate layer 340, and the cathode 350 constitute a light emitting element ED.

An encapsulation layer structure 400 in which inorganic films 410 and 430 and an organic film 420 are alternately disposed can be formed on the light emitting element ED and the lens layer LS. The encapsulating layer structure 400 is not limited thereto, and any one of the inorganic films 410 and 430 or the organic film 420 can include a plurality of inorganic films or a plurality of organic films.

In addition, the inorganic films 410 and 430 and the organic film 420 included in the encapsulation layer structure 400 are transparent insulating films. Furthermore, at least one of the inorganic films 410 and 430 and the organic film 420 included in the encapsulation layer structure 400 can function to reduce a step between the lens layer LS formed in the concave portion CV and the periphery thereof.

The lens layer LS provided in the light emitting display device of the present disclosure can be formed in the same process as the pixel defining film BNSP, and can have a lens having a refractive index difference, whereby it is possible to increase the light collection efficiency of the camera or the sensor located at the bottom side of the substrate without adding a separate process. Consequently, light sensing sensitivity can be improved, and reliability of the sensor and the camera can be increased.

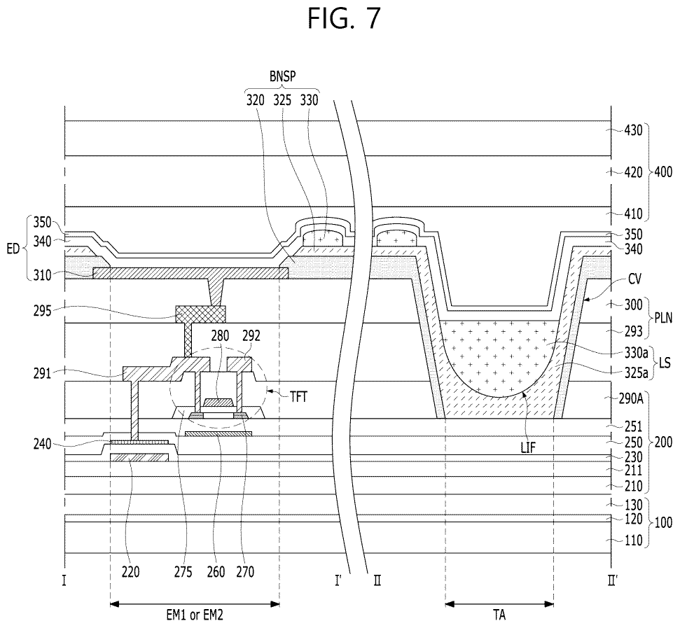

FIG. 7 is a sectional view showing a light emitting display device according to another embodiment of the present disclosure.

Referring to FIG. 7, the light emitting display device according to the another embodiment of the present disclosure is characterized in that a concave portion CV is formed not only in a planarization film PLN but also in a part 290A of an insulating film 200 under the planarization film PLN.

A light-shielding pixel defining film 320 is disposed along the side of the concave portion CV laterally located on the same layer as an oxide semiconductor layer 270, and can further block side light transmission at the side of the concave portion CV, thereby effectively preventing the oxide semiconductor layer 270 from being degraded by light.

In the light emitting display device according to the another embodiment of the present disclosure, a lens layer LS can be formed in the same process as the formation of a pixel defining film BNSP, and formation of the curved interface LIF of the lens layer LS in the concave portion CV can increase the efficiency of light that is collected to a transmission unit TA and improve the light sensitivity of a camera or a sensor located at the bottom side of a substrate 100.

In the light emitting display device according to the embodiments of the present disclosure, the oxide semiconductor layer 270 provided in the transistor TFT is more sensitive to light, and therefore a light-shielding pattern 260 is provided thereunder to prevent influence by external light, an anode 310 of a light emitting element ED located thereabove includes a reflective electrode to shield lower light and upper light, and a light-shielding pixel defining film 320 is provided along the side of the concave portion CV of the transmission unit TA to prevent the scattered incidence of light from the transmission unit TA with improved light collection efficiency to the side. That is, not only external light incident on the light-sensitive oxide semiconductor layer 270 from above and below but also internally scattered light transmitted from the transmission unit TA to the side can be blocked, thereby effectively preventing defects of the oxide semiconductor layer 270 caused by light. In addition, even if the transistor does not include the oxide semiconductor layer 270, if the transistor is a light-sensitive transistor, it is possible to prevent light-induced variability of the transistor and improve reliability of the transistor through a structure capable of blocking upper light, lower light, and side light incident on the transistor.

Meanwhile, in the light emitting display device according to the embodiments of the present disclosure, there is an advantage of increasing the light detection rate of the camera or the sensor at the bottom side of the substrate 100 when the lens layer LS is provided in the concave portion CV.

The lens layer LS can be formed in the concave portion CV of the insulating film provided to increase the transmittance of the transmission unit TA, and the light-shielding pixel defining film can be disposed on the side of the concave portion CV to prevent light passing through the transmission unit TA from scattering to the side. In addition, for the transistor including the oxide semiconductor layer that is sensitive to incidence of various kinds of light, the light-shielding pixel defining film can prevent light transmission not only from the top but also from the side, thereby stabilizing the characteristics of the transistor and preventing deterioration of the transistor.

For the transistor that requires high mobility for fast response speed in the second area where the transmission unit is located so as to correspond to the sensor or the camera and the subpixels have low resolution, internal scattering light can be shielded by the light collection structure of the lens layer LS and the light-shielding structure of the light-shielding pixel defining film disposed on the side of the concave portion, whereby the transistor in the second area includes a high-mobility oxide semiconductor layer without changing the structure of the transistor, preventing deterioration of the high-mobility transistor and achieving stable high brightness operation.

As a result, it is possible to realize a high-mobility transistor required for low resolution driving, enabling the application of a small-sized concave portion corresponding to the camera or the sensor and the application of the materials for various elements, which is more advantageous for securing process margins.

In the light emitting display device according to the embodiments of the present disclosure, a hole is formed in the insulating film of the substrate so as to have a size corresponding to the concave portion such that the camera or the sensor is provided, and the lens layer is provided in the hole of the insulating film, whereby the light detection rate can be increased based on the light collection efficiency of the lens layer and the power consumption required to drive the camera or the sensor can be reduced.

The light emitting display device according to the embodiments of the present disclosure has the advantage that the light-shielding pixel defining film is disposed on the side of the hole in the insulating film while the lens layer is provided in the hole of the insulating film to increase the light collection efficiency, thereby reducing the size of the hole and the size of the camera or the sensor and reducing the weight of the light emitting display device.

In the light emitting display device according to the embodiments of the present disclosure, the lens layer can be formed when the pixel defining film is formed without adding additional materials, thereby achieving single material implementation.

In the light emitting display device according to the embodiments of the present disclosure, transmission of light from the camera or the sensor to the periphery thereof can be prevented by the light-shielding pixel defining film provided on the side of the hole in the insulating film, thereby preventing changes in the characteristics of the transistor due to internal light scattering and improving reliability of the high-mobility transistor.

Furthermore, in the light emitting display device according to the embodiments of the present disclosure, it is possible to omit a material addition process, to reduce production energy, and to reduce the generation of greenhouse gases that can be generated due to the manufacturing process through process optimization, thereby achieving ESG (environmental/social/governance) goals.

In recent light emitting display devices, the camera or the sensor is provided in the display area AA rather than the non-display area NA such that the entire display area AA can be used for display. To this end, the camera or the sensor is provided in the area overlapping the display area AA.

Meanwhile, in the camera or the sensor, the concave portion CV is provided in the substrate 100 or in a plurality of insulating films on the substrate 100, the transmission unit TA having high light transmittance different from the light emitting unit is applied, and the light transmittance in the light transmission unit TA is increased to collect light. In this case, the second area in which the transmission unit TA is provided has low resolution subpixel disposition, and the low resolution second area requires high mobility of the transistor to compensate for the low subpixel disposition density. A high-mobility transistor can be more sensitive to light, requiring light-shielding of internally scattered light obliquely incident on the high-mobility transistor or transversely transmitted from the transmission unit in addition to direct external light incident on the high-mobility transistor from above and below.

The reflective anode or the light-shielding pixel defining film can be provided on the high-mobility transistor to shield upper external light, and the light-shielding pattern can be provided on a lower side of at least the channel of the oxide semiconductor layer thereunder to shield lower external light. In the light emitting display device according to the embodiments of the present disclosure, the light-shielding pixel defining film can be disposed on the side of the concave portion from which the insulating film has been removed, thereby effectively blocking light passing through the transmission unit from being transmitted to the side. Furthermore, the interface having the refractive index difference in the concave portion of the transmission unit can have a concave surface to increase the light collection efficiency in the concave portion of the transmission unit, whereby it is possible to prevent light from radiating from the transmission unit and to increase light reception sensitivity of the camera or the sensor.

The camera or the sensor can emit or radiate infrared light or ultraviolet light, and the light emitting display device of the present disclosure has the advantage that the light-shielding pixel defining film is provided at the lens layer and the side of the concave portion so as to correspond to the concave portion such that light incident on the substrate from above and light emitted by the camera or the sensor at the bottom side of the substrate directly pass through the concave portion in the transmission unit, thereby increasing light collection efficiency.

In the light emitting display device according to the embodiments of the present disclosure, therefore, it is possible to simultaneously improve sensing sensitivity of the camera or the sensor and reliability of the high-mobility transistor around the transmission unit.

A light emitting display device according to one embodiment of the present disclosure can comprise a substrate having a first area and a second area, a plurality of first light emitting units provided in the first area, a second light emitting unit and a transmission unit provided in the second area, the second light emitting unit and the transmission unit being spaced apart from each other, a pixel defining film disposed so as to surround the plurality of first light emitting units and the second light emitting unit, and a lens layer provided in the transmission unit, the lens layer comprising a first refractive index layer and a second refractive index layer located on the first refractive index layer and having a higher refractive index than the first refractive index layer, the lens layer having a curved interface provided between the first refractive index layer and the second refractive index layer.

In a light emitting display device according to one embodiment of the present disclosure, the first refractive index layer can extend to the pixel defining film.

In a light emitting display device according to one embodiment of the present disclosure, the pixel defining film can comprise a light-shielding pixel defining film and a light-transmissive pixel defining film, and the first refractive index layer is located on a same layer as the light-transmissive pixel defining film.

In a light emitting display device according to one embodiment of the present disclosure, the pixel defining film can comprise a light-shielding pixel defining film and a light-transmissive pixel defining film, and the first refractive index layer can comprise the same material as the light-transmissive pixel defining film.

In a light emitting display device according to one embodiment of the present disclosure, a spacer can be provided on a part of the light-transmissive pixel defining film, and the second refractive index layer can comprise the same material as the spacer.

In a light emitting display device according to one embodiment of the present disclosure, each of the plurality of first light emitting units and the second light emitting unit can comprise a light emitting element comprising an anode, an intermediate layer, and a cathode, a transistor connected to the light emitting element, and a planarization film provided between the light emitting element and the transistor, and the transmission unit can comprise a concave portion formed in the planarization film.

In a light emitting display device according to one embodiment of the present disclosure, an insulating film can be provided under the planarization film, and the concave portion can be further formed in the insulating film.

In a light emitting display device according to one embodiment of the present disclosure, the curved interface of the lens layer can be in a shape of being recessed so as to face a lower surface of the concave portion.

In a light emitting display device according to one embodiment of the present disclosure, the transistor can comprise an oxide semiconductor layer.

A light emitting display device according to one embodiment of the present disclosure can further comprise an encapsulation layer structure configured to cover the cathode. The encapsulation layer structure can comprise a plurality of transparent insulating films, and at least one of the plurality of transparent insulating films of the encapsulation layer structure can planarize the concave portion.

In a light emitting display device according to one embodiment of the present disclosure, the curved interface of the lens layer can be provided in the concave portion.

In a light emitting display device according to one embodiment of the present disclosure, the pixel defining film can comprise a light-shielding pixel defining film and a light-transmissive pixel defining film, and the light-shielding pixel defining film can be provided along a side of the concave portion.

In a light emitting display device according to one embodiment of the present disclosure, the light-shielding pixel defining film provided on the side of the concave portion can shield light between the lens layer and the transistor.

In a light emitting display device according to one embodiment of the present disclosure, the curved interface of the lens layer can have a surface area greater than a surface area of a lower surface of the concave portion.

In a light emitting display device according to one embodiment of the present disclosure, a spacer can be provided on a part of the light-transmissive pixel defining film, and the second refractive index layer can comprise the same material as the spacer.

In a light emitting display device according to one embodiment of the present disclosure, the first refractive index layer and the light-transmissive pixel defining film can be integrated, and the second refractive index layer can be spaced apart from the spacer.

In a light emitting display device according to one embodiment of the present disclosure, a refractive index of the second refractive index layer can be 0.2 to 0.8 greater than a refractive index of the first refractive index layer.

In a light emitting display device according to one embodiment of the present disclosure, a disposition density of the first light emitting units in the first area can be greater than a disposition density of the second light emitting unit in the second area.

In a light emitting display device according to one embodiment of the present disclosure, at least one of a camera, an infrared sensor, and an ultraviolet sensor can be provided in the second area of the substrate.

A light emitting display device according to one embodiment of the present disclosure can comprise: a substrate including a display area and a non-display area surrounding the display area; a plurality of subpixels emitting light provided in the display area and a transmission unit located between the subpixels; and a sensor unit disposed so as to correspond to the transmission unit, wherein a concave portion from which at least one insulating film on the substrate has been removed can be provided in the transmission unit, and a lens layer can be provided in the concave portion such that light incident on the substrate from above is condensed through the lens layer and collected by the sensor unit.

In a light emitting display device according to one embodiment of the present disclosure, a light-shielding film can be provided on a side of the concave portion.

As is apparent from the above description, a light emitting display device according to an embodiment of the present disclosure has the following effects.

In the light emitting display device according to the embodiments of the present disclosure, a concave portion is provided in the area of a substrate corresponding to a sensor and/or a camera, and a lens layer structure having a curved interface where a low refractive index layer and a high refractive index layer are joined to each other is applied to the concave portion, whereby it is possible to increase the light detection rate of light incident on the sensor and/or the camera from above the substrate through the light collection effect of the lens layer.

In the light emitting display device according to the embodiments of the present disclosure, the surface area of the curved interface of the lens layer structure where the low refractive index layer and the high refractive index layer are joined to each other is greater than the planar area of the concave portion, whereby it is possible to obtain higher sensing sensitivity due to the light collection effect by the lens layer structure and the increased surface area by the curved interface even if the planar size of the concave portion to which the lens layer structure is applied is reduced.

In the light emitting display device according to the embodiments of the present disclosure, a hole is formed in an insulating film of the substrate so as to have a size corresponding to the concave portion such that the camera or the sensor is provided, and the lens layer is provided in the hole of the insulating film, whereby it is possible to increase the light detection rate based on the light collection efficiency of the lens layer and to reduce the power consumption required to drive the camera or the sensor.

The light emitting display device according to the embodiments of the present disclosure has the advantage that a light-shielding pixel defining film is disposed on the side of the hole in the insulating film while the lens layer is provided in the hole of the insulating film to increase the light collection efficiency, thereby reducing the size of the hole and the size of the camera or the sensor and reducing the weight of the light emitting display device.

In the light emitting display device according to the embodiments of the present disclosure, the lens layer can be formed when the pixel defining film is formed without adding additional materials, thereby achieving single material implementation.

In the light emitting display device according to the embodiments of the present disclosure, transmission of light from the camera or the sensor to the periphery thereof can be prevented by the light-shielding pixel defining film provided on the side of the hole in the insulating film, thereby preventing changes in the characteristics of a transistor due to internal light scattering and improving reliability of the transistor.

Furthermore, in the light emitting display device according to the embodiments of the present disclosure, it is possible to omit a material addition process, to reduce production energy, and to reduce the generation of greenhouse gases that can be generated due to the manufacturing process through process optimization, thereby achieving ESG (environmental/social/governance) goals.

Those skilled in the art will understand that various modification and alternations are possible from the above description without departing from the technical idea of the present disclosure. Consequently, the technical scope of the present disclosure is defined by the appended claims, not by the detailed description of the present disclosure.

What is claimed is:

1. A light emitting display device comprising:
a substrate having a first area and a second area;
a plurality of first light emitting units provided in the first area;
a second light emitting unit and a transmission unit provided in the second area, the second light emitting unit and the transmission unit being spaced apart from each other;
a pixel defining film disposed to surround the plurality of first light emitting units and the second light emitting unit; and
a lens layer provided in the transmission unit, the lens layer comprising a first refractive index layer and a second refractive index layer located on the first refractive index layer and having a higher refractive index than the first refractive index layer,
wherein the lens layer has a curved interface provided between the first refractive index layer and the second refractive index layer.

2. The light emitting display device according to claim 1, wherein the first refractive index layer extends to overlap the pixel defining film.

3. The light emitting display device according to claim 1, wherein:
the pixel defining film comprises a light-shielding pixel defining film and a light-transmissive pixel defining film, and
the first refractive index layer is located on a same layer as the light-transmissive pixel defining film.

4. The light emitting display device according to claim 1, wherein:
the pixel defining film comprises a light-shielding pixel defining film and a light-transmissive pixel defining film, and
the first refractive index layer comprises a same material as the light-transmissive pixel defining film.

5. The light emitting display device according to claim 4, wherein:
a spacer is provided on a part of the light-transmissive pixel defining film, and
the second refractive index layer comprises a same material as the spacer.

6. The light emitting display device according to claim 1, wherein:
each of the plurality of first light emitting units and the second light emitting unit comprises a light emitting element, a transistor connected to the light emitting element, and a planarization film provided between the light emitting element and the transistor,
each light emitting element comprising an anode, an intermediate layer, and a cathode, and
the transmission unit comprises a concave portion in the planarization film.

7. The light emitting display device according to claim 6, wherein:
an insulating film is provided under the planarization film, and
the concave portion of the transmission unit is further provided in the insulating film.

8. The light emitting display device according to claim 6, wherein the curved interface of the lens layer is in a recessed shape and faces a lower surface of the concave portion of the transmission unit.

9. The light emitting display device according to claim 6, wherein the transistor comprises an oxide semiconductor layer.

10. The light emitting display device according to claim 6, further comprising:
an encapsulation layer structure configured to cover the cathode, wherein:
the encapsulation layer structure comprises a plurality of transparent insulating films, and
at least one of the plurality of transparent insulating films of the encapsulation layer structure planarizes the concave portion of the transmission unit.

11. The light emitting display device according to claim 6, wherein the curved interface of the lens layer is provided in the concave portion of the transmission unit.

12. The light emitting display device according to claim 6, wherein:
the pixel defining film comprises a light-shielding pixel defining film and a light-transmissive pixel defining film, and
the light-shielding pixel defining film is provided along a side of the concave portion of the transmission unit.

13. The light emitting display device according to claim 12, wherein the light-shielding pixel defining film provided on the side of the concave portion of the transmission unit shields light between the lens layer and the transistor.

14. The light emitting display device according to claim 6, wherein the curved interface of the lens layer has a surface area greater than a surface area of a lower surface of the concave portion of the transmission unit.

15. The light emitting display device according to claim 3, wherein:
a spacer is provided on a part of the light-transmissive pixel defining film, and
the second refractive index layer comprises a same material as the spacer.

16. The light emitting display device according to claim 15, wherein:
the first refractive index layer and the light-transmissive pixel defining film are integrated, and
the second refractive index layer is spaced apart from the spacer.

17. The light emitting display device according to claim 1, wherein a refractive index of the second refractive index layer is 0.2 to 0.8 greater than a refractive index of the first refractive index layer.

18. The light emitting display device according to claim 1, wherein a disposition density of the first light emitting units in the first area is greater than a disposition density of the second light emitting unit in the second area.

19. The light emitting display device according to claim 1, wherein at least one of a camera, an infrared sensor, and an ultraviolet sensor is provided in the second area of the substrate.

20. A light emitting display device comprising:
a substrate including a display area and a non-display area adjacent to the display area;
a plurality of subpixels configured to emit light provided in the display area and a transmission unit located between the plurality of subpixels;
a sensor unit disposed to correspond to the transmission unit;
a concave portion provided in the transmission unit;
a lens layer provided in the concave portion; and
a light-shielding film on a side of the concave portion.
